(19) United States
(12) Patent Application Publication
(10) Pub. No.: US 2025/0338562 A1
(43) Pub. Date: Oct. 30, 2025

(54) SEMICONDUCTOR DEVICE AND FORMING METHOD WITH CHANNEL FEATURE THEREOF

(71) Applicant: Taiwan Semiconductor Manufacturing Co., Ltd., Hsinchu (TW)

(72) Inventors: Che Chi Shih, Taoyuan City (TW); Chia-Hao Yu, New Taipei City (TW); Zhi-Chang Lin, Zhubei City (TW); Ku-Feng Yang, Baoshan Township (TW); Tsung-Kai Chiu, Zhubei City (TW); Szuya Liao, Zhubei City (TW)

(21) Appl. No.: 19/262,443

(22) Filed: Jul. 8, 2025

Related U.S. Application Data
(63) Continuation of application No. 18/616,701, filed on Mar. 26, 2024.
(60) Provisional application No. 63/611,338, filed on Dec. 18, 2023.

(51) Int. Cl. H10D 30/67; H10D 30/01; H10D 30/43; H10D 62/10; H10D 64/01; H10D 84/01; H10D 84/03; H10D 84/83

(52) U.S. Cl. CPC H10D 30/6735; H10D 30/014; H10D 30/43; H10D 30/6757; H10D 62/118; H10D 64/017; H10D 84/0128; H10D 84/0135; H10D 84/038; H10D 84/83

(57) ABSTRACT

A method includes forming a multi-layer stack including a plurality of semiconductor nanostructures. The multi-layer stack includes a semiconductor nanostructure, and a sacrificial semiconductor layer over the semiconductor nanostructure. The method further includes depositing a semiconductor layer over and contacting the semiconductor nanostructure, removing the sacrificial semiconductor layer, and forming a replacement gate stack encircling a combined region of the semiconductor nanostructure and the semiconductor layer.

### PRIORITY CLAIM AND CROSS-REFERENCE

This application is a continuation of U.S. patent application Ser. No. 18/616,701, filed on Mar. 26, 2024, which application claims the benefit of the following provisionally filed U.S. Patent application: Application No. 63/611,338, filed on Dec. 18, 2023, and entitled “SEMICONDUCTOR DEVICE AND FORMING METHOD THEREOF,” which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2-5, 6A, 6B, 6C, 6D, 7, 8A, 8B, 9A, 9B, 10A, 10B, 10C, 11A, 11B, 11C, 12A, 12B, and 12C are views of intermediate stages in the manufacturing of CFETs in accordance with some embodiments.

FIGS. 13-15, 16A, 16B, 17-18, 19A, 19B, and 19C are views of intermediate stages in the manufacturing of CFETs in accordance with some embodiments.

FIGS. 20, 21A, 21B, and 21C are views of intermediate stages in the manufacturing of CFETs in accordance with some embodiments.

FIGS. 22-24, 25A, 25B, 25C, 25D, 26, 27A, 27B, 27C, 28A, 28B, and 28C are views of intermediate stages in the manufacturing of CFETs in accordance with some embodiments.

FIG. 29 illustrates a process flow for forming a CFET structure in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Complementary Field-Effect Transistor (CFET) structure and the method of forming the same are provided. The channel regions of the transistors in the CFET structures are modified to have increased effective channel width.

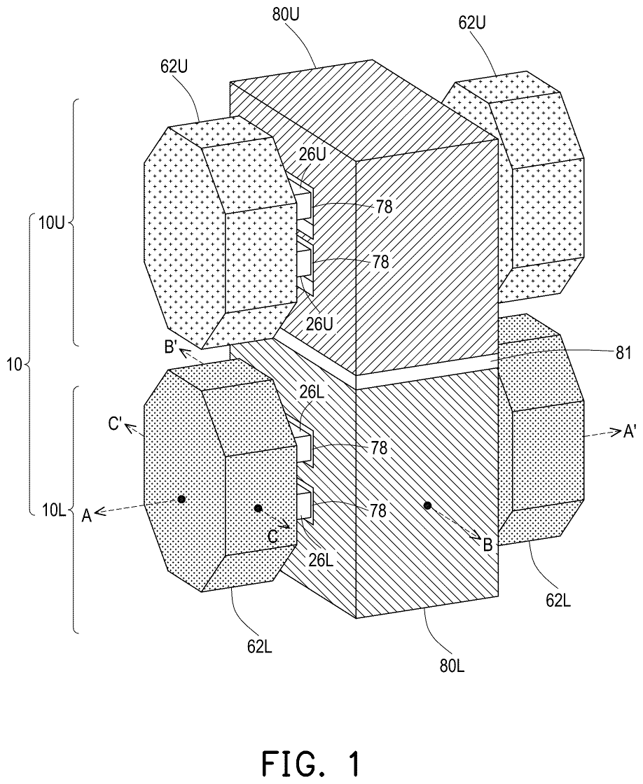

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the CFETs may be applied to other types of transistors (e.g., FinFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26 of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Cross-section C-C′ is a vertical cross-section that is parallel to cross-section B-B′ and extends through the source/drain regions 62 of the CFETs. Subsequent figures may refer to these reference cross-sections for clarity.

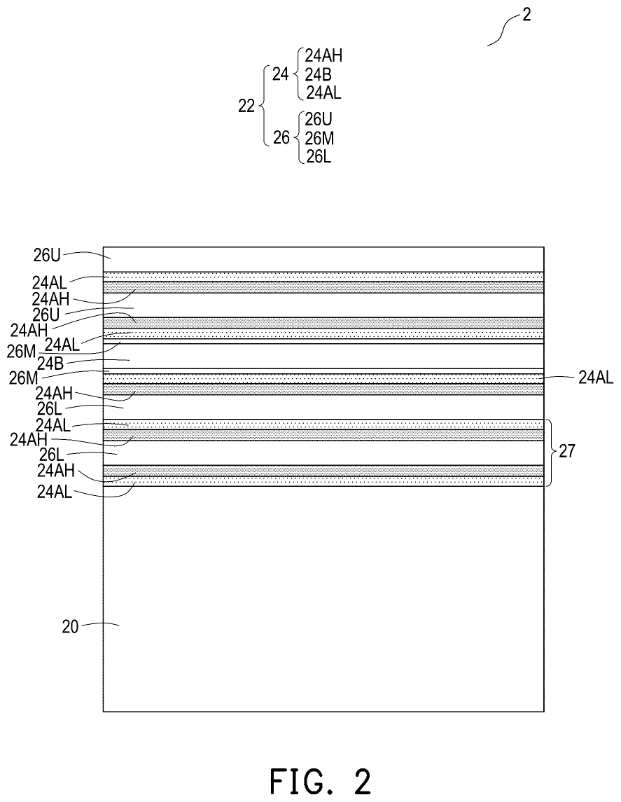

FIGS. 2-5, 6A, 6B, 6C, 6D, 7, 8A, 8B, 9A, 9B, 10A, 10B, 10C, 11A, 11B, 11C, 12A, 12B, and 12C illustrate the views of intermediate stages in the formation of CFETs (as schematically represented in FIG. 1) in accordance with some embodiments. In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor, or the like, or combinations thereof.

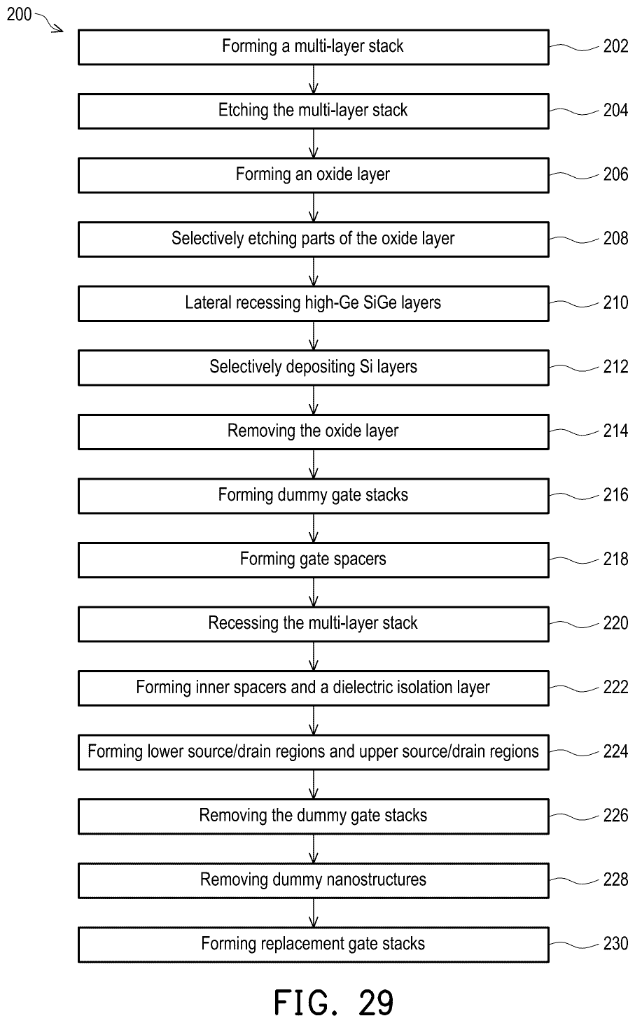

A multi-layer stack 22 is deposited, for example, through epitaxy processes. The respective process is illustrated as process 202 in the process flow 200 as shown in FIG. 29. To form the multi-layer stack 22, alternating semiconductor materials (arranged as illustrated) may be deposited over the semiconductor substrate 20. The alternating semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

In accordance with some embodiments, multi-layer stack 22 include silicon layers 26 (including silicon layers 26U and 26L, and possibly 26M), which may be free from germanium. A plurality of dummy silicon germanium (SiGe) layers 24 having different germanium concentrations are formed. In accordance with some embodiments, dummy SiGe layers 24A include high-Ge SiGe layer 24AH having a high germanium concentration GC24AH, a mid-Ge SiGe layer 24B having a medium germanium concentration GC24BM, and low-Ge SiGe layers 24AL having a low germanium concentration GC24AL.

The germanium concentrations have the relationship GC24AL<GC24BM<GC24AH. For example, the germanium concentration GC24AL may be in the range between about 10 percent and about 35 percent, the germanium concentration GC24BM may be in the range between about 20 percent and about 40 percent, and the germanium concentration GC24AH may be in the range between about 35 percent and about 50 percent. The differences (GC24AH-GC24BM) and (GC24BM-GC24AL) may be higher than about 5 percent or higher than about 10 percent.

In accordance with some embodiments, a silicon layer 26U or 26L and the overlaying and/or underlying high-Ge SiGe layer 24AH and low-Ge SiGe layer 24AL collectively form a unit 27, which is used as a base for modifying the shape and the materials of channels. The unit may be repeated (and stacked) for forming the upper FET and/or lower FET.

In accordance with some embodiments, silicon layers 26U and 26L have thicknesses in the range between about 2 nm and about 15 nm. The thicknesses of SiGe layers 24A and 24B may be in the range between about 2 nm and about 15 nm, and may also be equal to or smaller than the thickness of silicon layers 26U and 26L. In accordance with some embodiments, silicon layer 26M (if formed) may be thinner than silicon layers 26U and 26L.

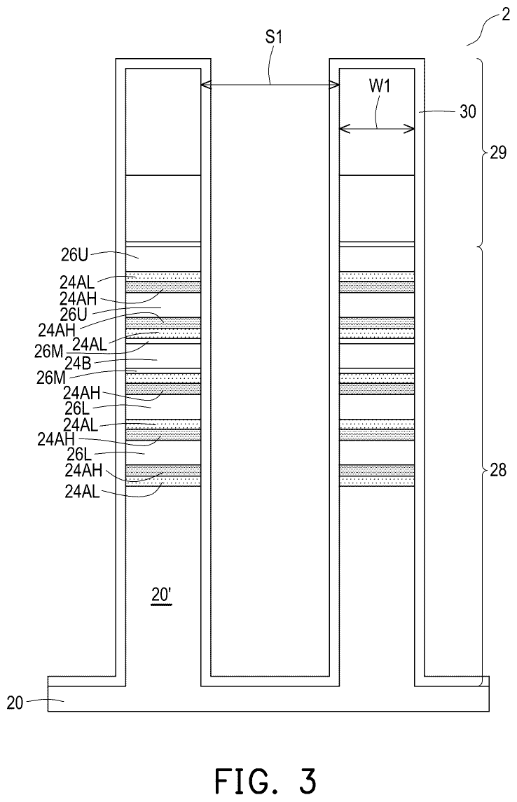

Referring to FIG. 3, a patterning process may be applied to etch the multi-layer stack 22 as well as the semiconductor substrate 20 to define the semiconductor strips 28, which include semiconductor fins 20′, the dummy nanostructure 24, and the semiconductor nanostructures 26. The respective process is illustrated as process 204 in the process flow 200 as shown in FIG. 29. In accordance with some embodiments, the patterning process includes forming and patterning hard masks 29, which may comprise silicon nitride, and using the patterned hard masks 29 to etch the underlying materials. In accordance with some embodiments, the width W1 of semiconductor strips 28 and the spacing S1 between neighboring semiconductor strips 28 may be in the range between about 10 nm and about 100 nm. The etching may be performed by any acceptable etch process, such as a Reactive Ion Etch (RIE), Neutral Beam Etch (NBE), the like, or a combination thereof. The etching may be anisotropic.

The lower semiconductor nanostructures 26L will provide channel regions for the lower nanostructure-FETs of the CFETs. The upper semiconductor nanostructures 26U will provide the channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures. The isolation structures and the middle semiconductor nanostructures 26M may define boundaries of the lower nanostructure-FETs and the upper nanostructure-FETs.

Next, oxide layer 30 is formed. The respective process is illustrated as process 206 in the process flow 200 as shown in FIG. 29. In accordance with some embodiments, oxide layer 30 is formed through an oxidation process, so that the sidewall surface portions of the semiconductor materials in semiconductor strips 28 are oxidized. The oxidation process may be a thermal oxidation process. The surface portions of silicon layers 26U and 26L are oxidized as silicon oxide, and the surface portions of silicon germanium layers 24AH, 24B, and 24AL are oxidized as silicon germanium oxide, which may be porous. Silicon germanium layers 24AH also have higher percentages of germanium oxide than silicon germanium layers 24B and 24AL. In accordance with some embodiments, there may be no oxide (or may be oxide) formed on mark masks 29, depending on its material.

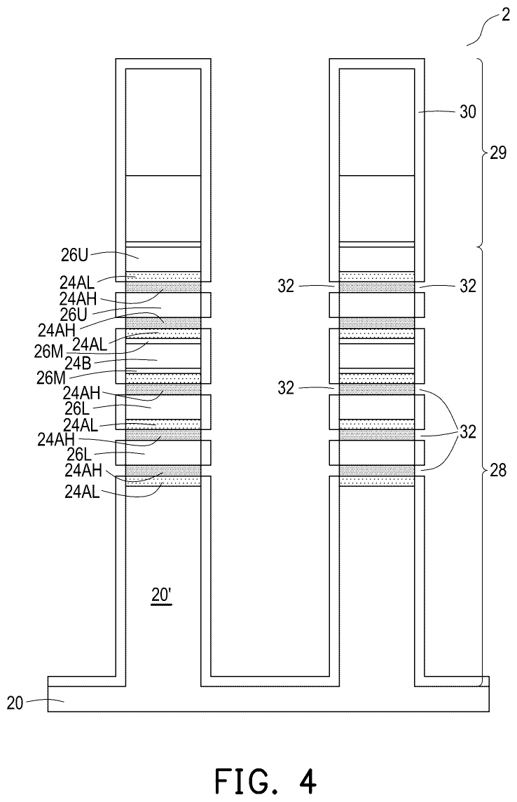

FIG. 4 illustrates the selective etching of some portions of the oxide layer 30. The respective process is illustrated as process 208 in the process flow 200 as shown in FIG. 29. The etching may be performed using water, HCl, NH, OH, or the like. In the etching process, the portions of the oxide layer 30 having higher germanium oxide percentages have higher etching rates than the portions of the oxide layer 30 having lower germanium oxide percentages. Accordingly, the portions of the oxide layer 30 on the sidewall of the high-Ge SiGe layer 24AH are etched faster.

The etching process is controlled, so that the portions of the oxide layer 30 formed from high-Ge SiGe layer 24AH are removed, forming openings 32, through which the sidewalls of high-Ge silicon germanium layers 24AH are exposed. Other portions of the semiconductor strips 28 including silicon layers 26 and silicon germanium layers 24B and 24AL are still protected by the respective portions of the oxide layer 30.

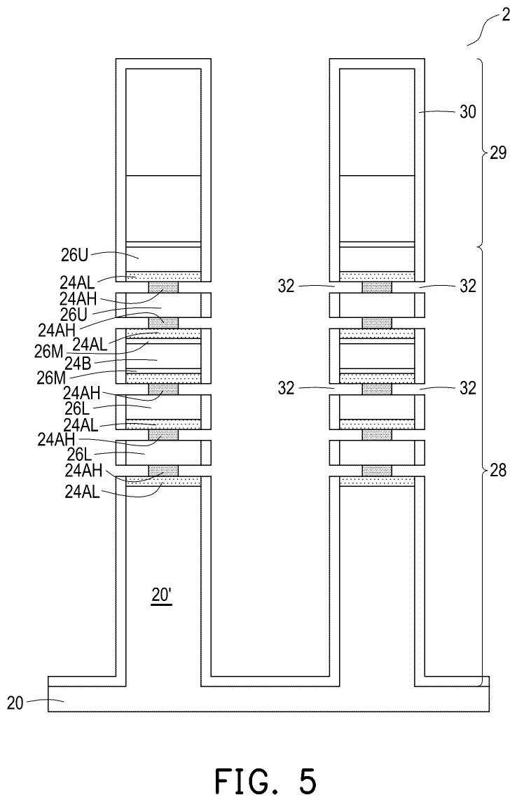

Referring to FIG. 5, the exposed high-Ge silicon germanium layers 24AH are laterally recessed in an etching process. The respective process is illustrated as process 210 in the process flow 200 as shown in FIG. 29. The etching may be performed in a dry etching process, for example, using HCl, Cl₂, or the like as etching gases. The etching process is stopped when the middle portions of high-Ge silicon germanium layers 24AH remain unetched, which middle portions will be replaced with replacement gate stacks in subsequent processes.

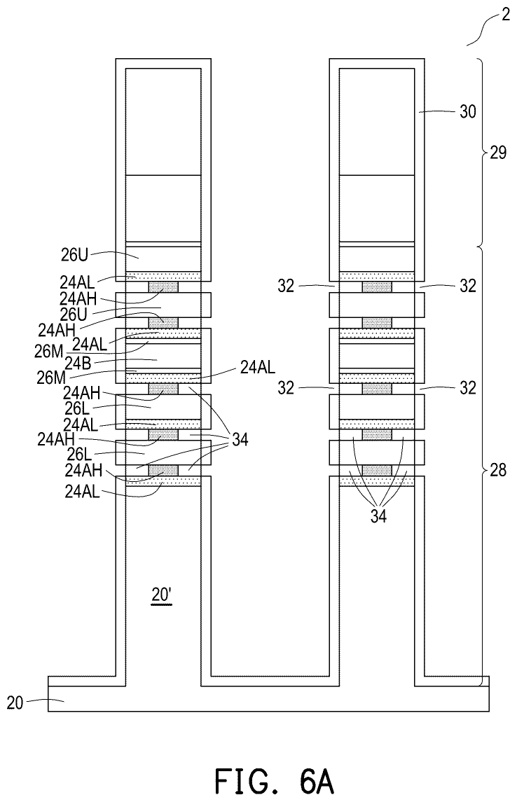

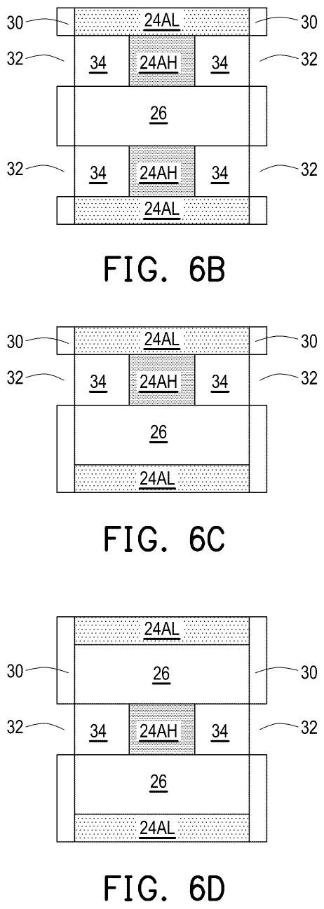

FIG. 6A illustrates the regrowth of semiconductor layer 34 in accordance with some embodiments. The respective process is illustrated as process 212 in the process flow 200 as shown in FIG. 29. In accordance with some embodiments, semiconductor layers 34 are silicon layers, which are free from germanium or substantially free from germanium (for example with less than about 2 atomic percent germanium). Accordingly, semiconductor layers 34 are alternatively referred to as silicon layers 34. The regrowth is selective epitaxy, for example, by conducting an etching gas such as HCl along with the precursor (such as silane, disilane, dichlorosilane, or the like) for the growth of silicon. Accordingly, silicon is grown on high-Ge silicon germanium layers 24AH. The oxide layer 30 may function as an inhibition layer so that semiconductor layer 34 is not grow on the oxide layer 30.

In accordance with some embodiments, the sidewalls of the high-Ge silicon germanium layers 24AH facing openings 30 are on (100) surfaces, while the top and bottom surfaces of the exposed surfaces of low-Ge silicon germanium layers 24AL and silicon layers 26 are on (110) surfaces. The growth rate on the (100) surfaces is greater (for example, three times greater) than on the (110) surfaces. Accordingly, the net effect of the different growth rates and the conduction of the etching gas results in the semiconductor material to be selectively grown on the sidewalls of high-Ge silicon germanium layers 24AH, but not on the exposed top and bottom surfaces of low-Ge silicon germanium layers 24AL and silicon layers 26.

In accordance with some embodiments in which there is growth on the exposed surfaces of low-Ge silicon germanium layers 24AL and silicon layers 26, a plurality of growth and etch-back cycles may be performed. In the etch-back process, the etching gas (such as HCl) is used to etch back the grown silicon layer on the exposed surfaces of low-Ge silicon germanium layers 24AL and silicon layers 26. Each of the growth and etch-back cycle results in a layer of silicon to be grown on the sidewalls of high-Ge silicon germanium layers 24AH, but not on the exposed top and bottom surfaces of low-Ge silicon germanium layers 24AL and silicon layers 26.

In the structure shown in FIG. 6A, the silicon layers 34 grown overlying and underlying silicon layer (including silicon layers 26U and 26L) collectively form a H-shape as along with the silicon layers 26U and 26L, as shown in FIG. 6B, which illustrates an amplified region as in FIG. 6A. Depending on the structure of the multi-layer stack, the silicon layers 34 grown overlying and underlying silicon layer 26U may also form a U-shape as shown in FIG. 6C, or an O-shape as shown in FIG. 6D.

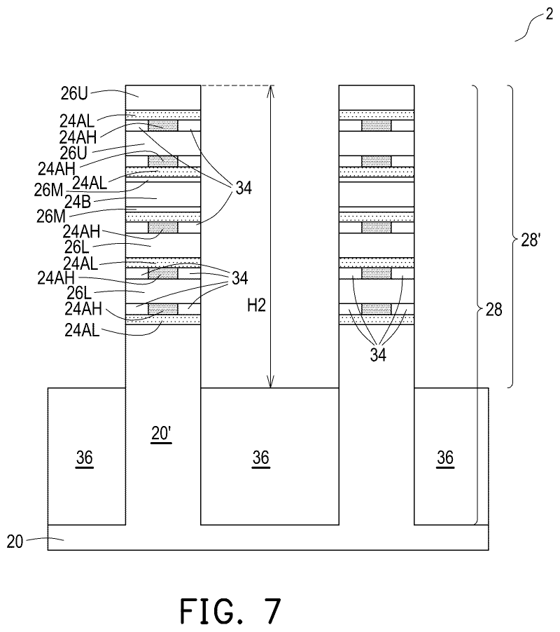

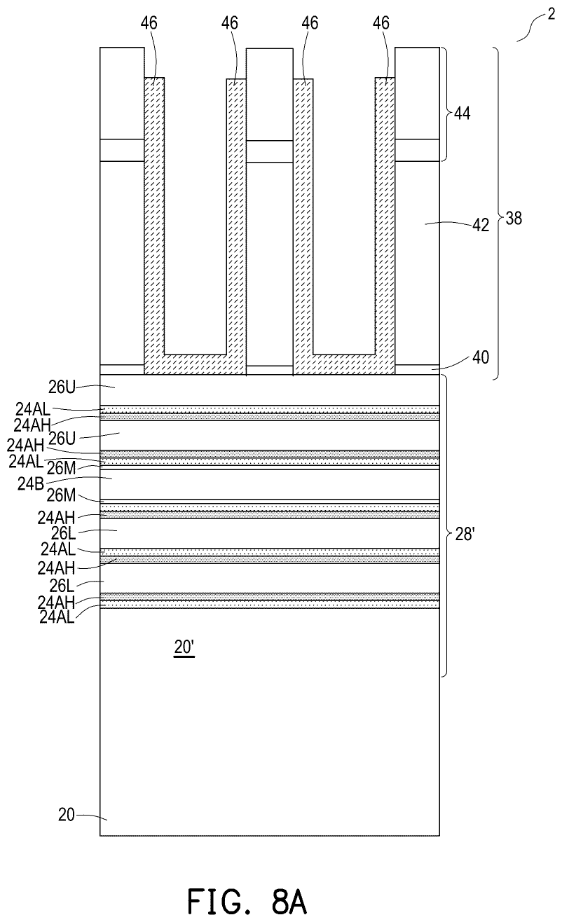

After the growth of silicon layer 34, oxide layer 30 (FIG. 6A) is removed, for example, in a dry etching process or a wet etching process. The resulting structure is shown in FIG. 7. The respective process is illustrated as process 214 in the process flow 200 as shown in FIG. 29. The semiconductor materials in semiconductor strips 28 are not etched.

As also illustrated by FIG. 7, STI regions 36 are formed over the substrate 20 and between adjacent semiconductor strips 28. STI regions 36 may include a dielectric liner and a dielectric material over the dielectric liner. Each of the dielectric liner and the dielectric material may include an oxide such as silicon oxide, a nitride, such as silicon nitride, the like, or a combination thereof. STI regions 36 are then recessed, and the top portions of semiconductor strips 28 are referred to as protruding semiconductor fins 28′, which may have heights H₂ in the range between about 50 nm and about 100 nm.

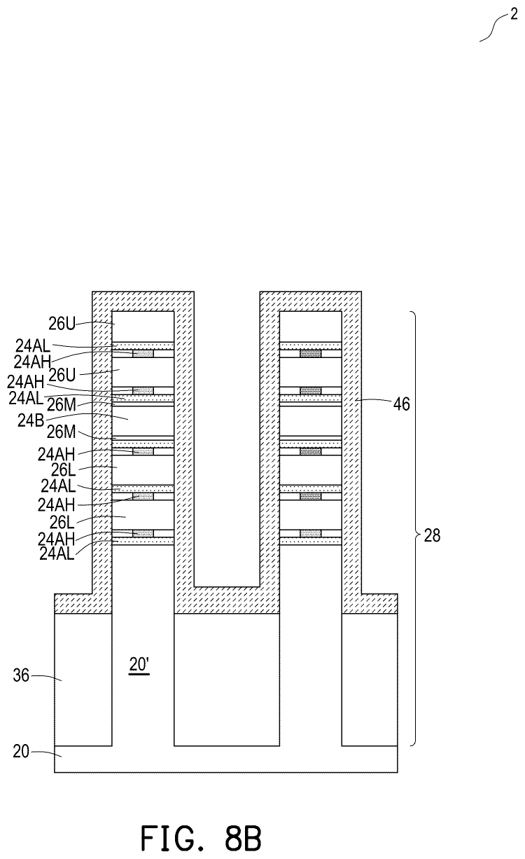

FIGS. 8A and 8B illustrate the cross-sections A-A′ and C-C′, respectively, in FIG. 1 in accordance with some embodiments. After the STI regions 36 are formed, dummy gate stacks 38 may be formed over and along the sidewalls of the upper portions of the protruding semiconductor fins 28′. The respective process is illustrated as process 216 in the process flow 200 as shown in FIG. 29. Forming the dummy gate stacks 38 may include forming dummy dielectric layer 40 on the protruding semiconductor fins 28′. Dummy dielectric layer 40 may be formed of or comprise, for example, silicon oxide, silicon nitride, a combination thereof, or the like, and may be deposited or thermally grown according to acceptable techniques.

A dummy gate layer 42 is formed over the dummy dielectric layer 40. The dummy gate layer 42 may be deposited, for example, through Physical Vapor Deposition (PVD), CVD, or other techniques, and then planarized, such as by a CMP process. The material of dummy gate layer 42 be conductive or non-conductive, and may be selected from a group including amorphous silicon, polycrystalline-silicon (polysilicon), poly-crystalline silicon-germanium (poly-SiGe), or the like. A mask layer 44 is formed over the planarized dummy gate layer 42, and may include, for example, silicon nitride, silicon oxynitride, or the like. Next, the mask layer 44 may be patterned through photolithography and etching processes to form a mask, which is then used to etch and pattern dummy gate layer 42, and possibly the dummy dielectric layer 40. The remaining portions of mask layer 44, dummy gate layer 42, and dummy dielectric layer 40 form dummy gate stacks 38.

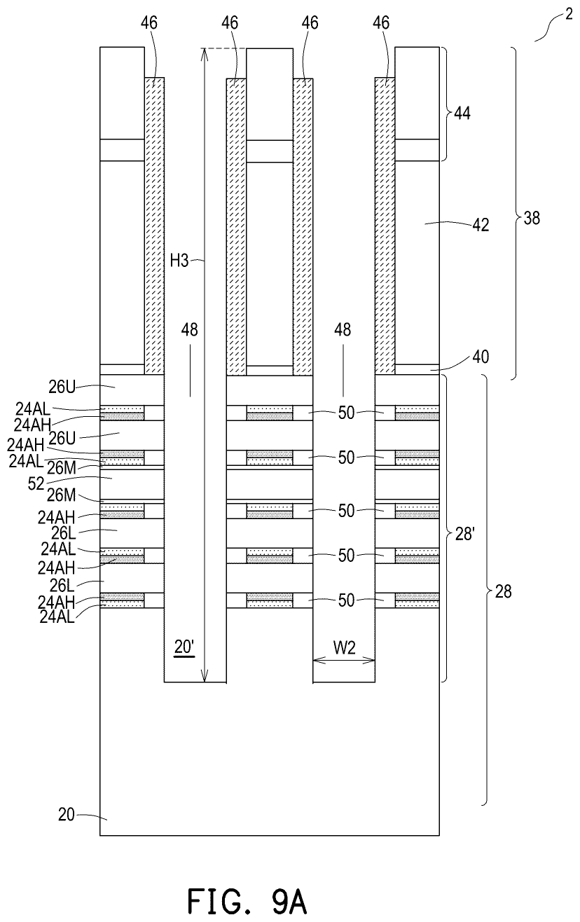

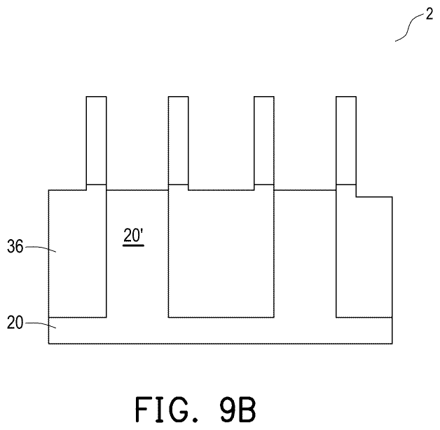

In FIGS. 8A and 8B, spacer layer 46 is deposited through a conformal deposition process. The applicable dielectric materials may include silicon oxide, silicon nitride, silicon oxynitride, silicon oxycarbonitride, or the like, which may be formed by a deposition process such as CVD, ALD, or the like. Next, an anisotropic etching process is performed to etch spacer layer 46, and the remaining portions form gate spacers 46 (FIG. 9A). The respective process is illustrated as process 218 in the process flow 200 as shown in FIG. 29.

In a subsequent process, as shown in FIGS. 9A and 9B, source/drain recesses 48 are formed in semiconductor strips 28. The respective process is illustrated as process 220 in the process flow 200 as shown in FIG. 29. The source/drain recesses 48 are formed through etching, and may extend through the multi-layer stacks 22 and into the semiconductor strips 20′. In the etching processes, the gate spacers 46 and the dummy gate stacks 38 mask some portions of the semiconductor strips 28. The etching may include a single etch process or multiple etch processes. Timed etch processes may be used to stop the etching of the source/drain recesses 48 upon source/drain recesses 48 reaching a desired depth.

In accordance with some embodiments, the height H3 of the structure higher than the bottoms of the source/drain recesses 48 may be in the range between about 200 nm and about 300 nm, and the width W2 of the source/drain recesses 48 may be smaller than about 20 nm.

As also shown in FIGS. 9A and 9B, inner spacers 50 and dielectric isolation layers 52 are formed. The respective process is illustrated as process 222 in the process flow 200 as shown in FIG. 29. Forming inner spacers 50 and dielectric isolation layers 52 may include an etching process that laterally etches the dummy nanostructures 24A (including high-Ge SiGe layer 24AH and the low-Ge SiGe layer 24AL), and removes the dummy nanostructure 24B. The etching process may be isotropic and may be selective to the material of the dummy nanostructures 24, so that the dummy nanostructures 24A are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A.

Inner spacers 50 are formed on sidewalls of the recessed dummy nanostructures 24A, and dielectric isolation layers 52 are formed between the upper semiconductor nanostructures 26U (collectively) and the lower semiconductor nanostructures 26L (collectively). As subsequently described in greater detail, source/drain regions will be subsequently formed in the source/drain recesses 48, and the dummy nanostructures 24A will be replaced with corresponding gate structures. The inner spacers 50 act as isolation features between the subsequently formed source/drain regions and the subsequently formed gate structures. Further, the inner spacers 50 may be used to prevent damage to the subsequently formed source/drain regions by subsequent etch processes, such as the etch processes used to form gate structures.

Dielectric isolation layers 52 (for example, formed of SiOCN), on the other hand, are used to isolate the upper semiconductor nanostructures 26U (collectively) from the lower semiconductor nanostructures 26L (collectively). Further, middle semiconductor nanostructures 26M and the dielectric isolation layers 52 may define the boundaries of the lower nanostructure-FETs and the upper nanostructure-FETs.

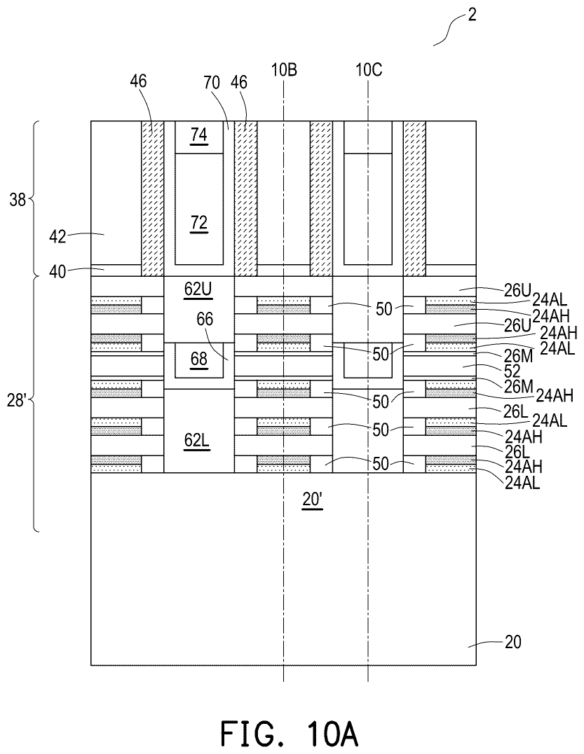

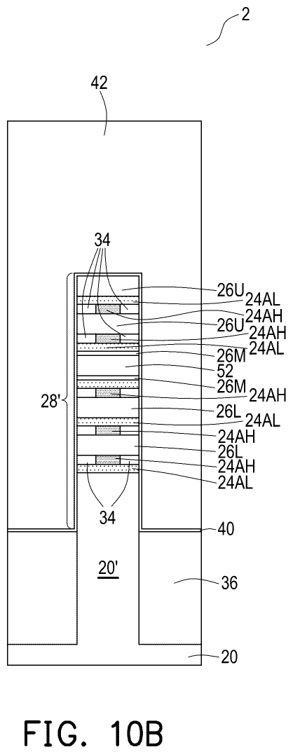

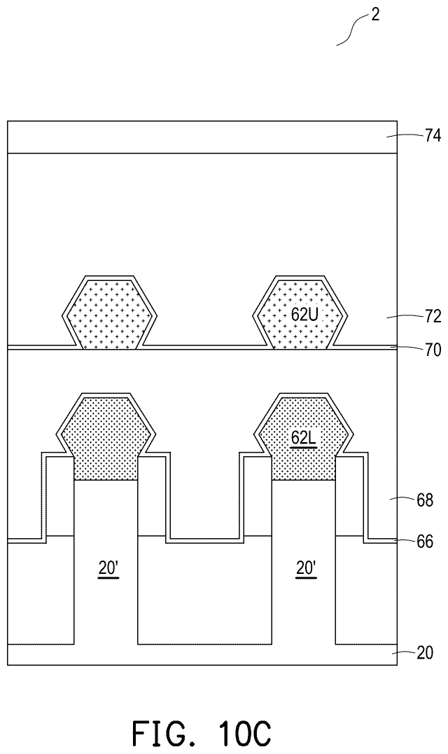

Referring to FIGS. 10A, 10B, and 10C, lower epitaxial source/drain regions 62L and upper epitaxial source/drain regions 62U are formed. The respective process is illustrated as process 224 in the process flow 200 as shown in FIG. 29. FIGS. 10A, 10B, and 10C illustrate the cross-sections A-A′, B-B′, and C-C′, respectively, in FIG. 1. The lower epitaxial source/drain regions 62L are formed in the lower portions of the source/drain recesses 48, and are in contact with the lower semiconductor nanostructures 26L, but are not in contact with the upper semiconductor nanostructures 26U. Inner spacers 50 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like, which may have an n-type dopant concentration greater than about 1E21/cm³.

When lower epitaxial source/drain regions 62L are p-type source/drain regions, the respective material may include silicon or silicon germanium, which is doped with a p-type dopant such as boron, indium, or the like. The boron concentration may be greater than about 5E20/cm³. The lower epitaxial source/drain regions 62L may be in-situ doped, and may be, or may not be, implanted with the corresponding p-type or n-type dopants. During the epitaxy of the lower epitaxial source/drain regions 62L, the upper semiconductor nanostructures 26U may be masked to prevent undesired epitaxial growth on the upper semiconductor nanostructures 26U. After the lower epitaxial source/drain regions 62L are grown, the masks on the upper semiconductor nanostructures 26U may then be removed.

A first contact etch stop layer (CESL) 66 and a first ILD 68 are then formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

Upper epitaxial source/drain regions 62U are then formed in the upper portions of the source/drain recesses 48. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L. For example, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant. A second CESL 70 and a second ILD 72, which may be formed of materials selected from the same candidate materials for forming the first CESL 66 and the first ILD 68, respectively, are formed over the upper epitaxial source/drain regions 62U.

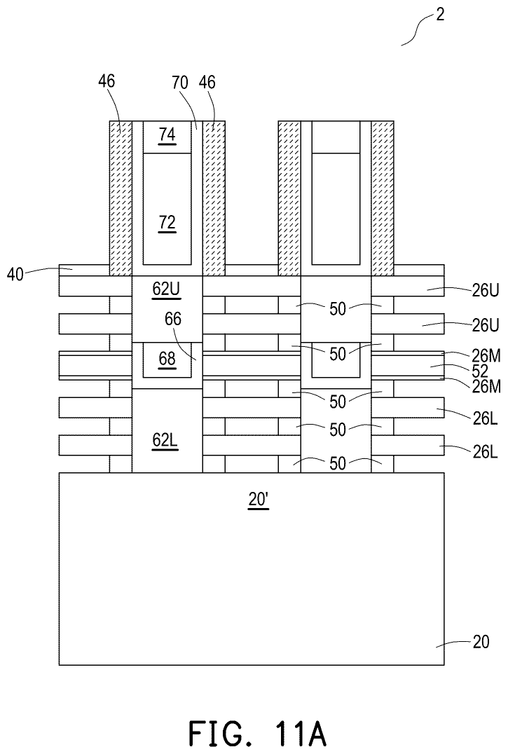

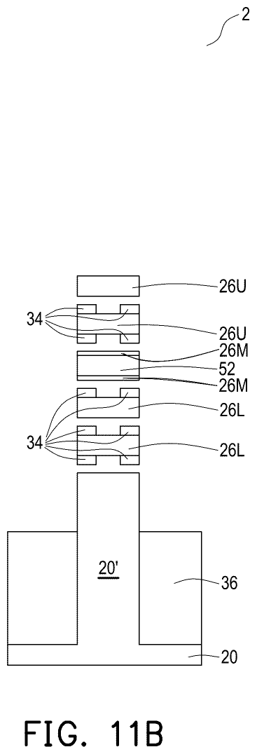

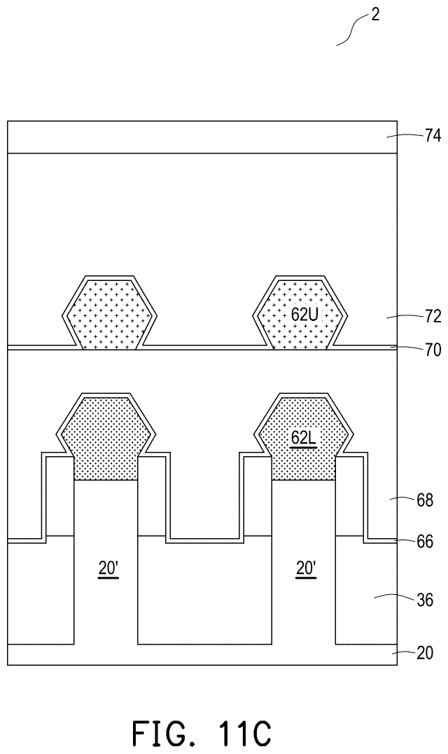

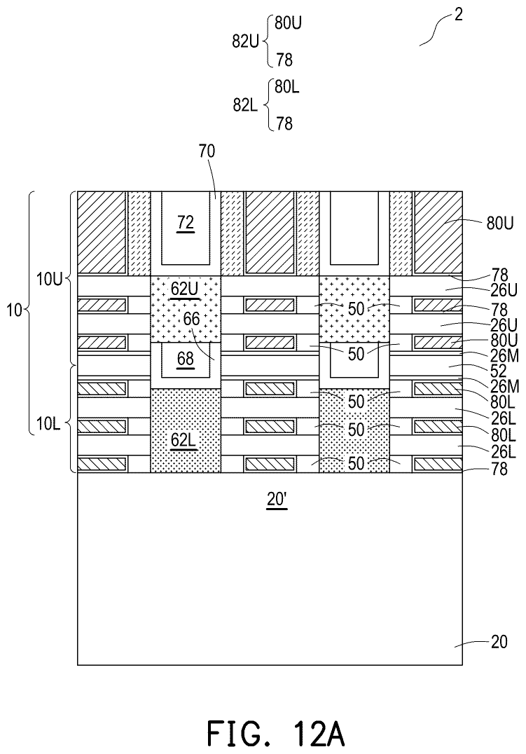

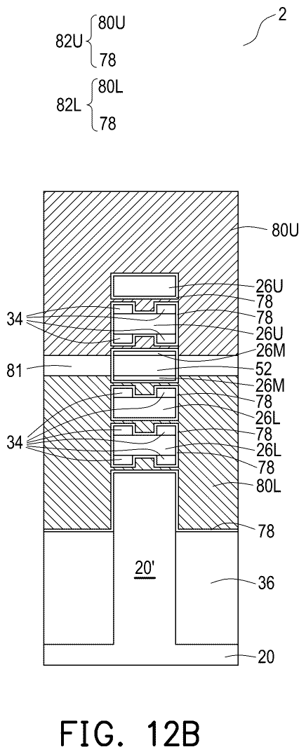

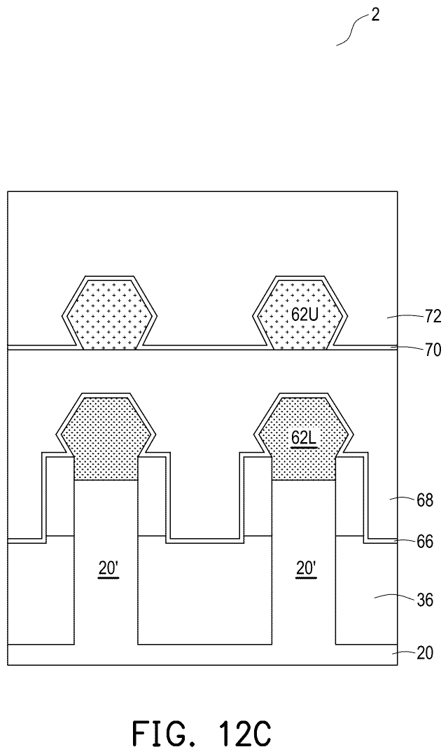

FIGS. 11A, 11B, 11C, 12A, 12B, and 12C illustrate a replacement gate process to replace the dummy gate stacks 38 and the dummy nanostructures 24A with gate stacks 82 (including 82U and 82L). The replacement gate process includes first removing the dummy gate stacks 38 and the remaining portions of the dummy nanostructures 24A.

Referring to FIGS. 11A, 11B, 11C, the dummy gate stacks 38 are removed in one or more etching processes, so that recesses are defined between the gate spacers 46, and the upper portions of the semiconductor strips 28 are exposed. The respective process is illustrated as process 226 in the process flow 200 as shown in FIG. 29. The remaining portions of the high-Ge SiGe layer 24AH and low-Ge SiGe layer 24AL are then removed through etching, so that the recesses extend between the semiconductor nanostructures 26. The respective process is illustrated as process 228 in the process flow 200 as shown in FIG. 29. In the etching process, both of the high-Ge SiGe layer 24AH and low-Ge SiGe layer 24AL are etched at a faster rate than the semiconductor nanostructures 26, semiconductor layers 34, the dielectric isolation layers 52, and the inner spacers 50. The etching may be isotropic. The etch process may include a wet etch process using tetramethylammonium hydroxide (TMAH), ammonium hydroxide (NH₄OH), or the like.

Then, as shown in FIGS. 12A, 12B, and 12C, replacement gate stacks 82L and 82U are formed, which include gate dielectrics 78 and gate electrodes 80L and 80U, respectively. The respective process is illustrated as process 230 in the process flow 200 as shown in FIG. 29. Gate dielectrics 78 are deposited in the recesses between the gate spacers 46 and on (and wrap around) the exposed semiconductor nanostructures 26 and semiconductor layers 34.

The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation process of the gate dielectrics 78 may include a conformal deposition process selected from molecular-beam deposition (MBD), ALD, PECVD, and the like.

Lower gate electrodes 80L are formed on the gate dielectrics 78 around the lower semiconductor nanostructures 26L. The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, titanium aluminum nitride, tantalum aluminum, Mo, R11, combinations thereof, or the like. In accordance with alternative embodiments, the lower gate electrodes 80L include a p-type work function tuning layer, which may be formed of titanium nitride, tantalum nitride, Mo, R11, combinations thereof, or the like.

In some embodiments, dielectric isolation layer 81 may be optionally formed on the lower gate electrodes 80L to separate the lower gate electrodes 80L from the subsequently formed upper gate electrodes 80U. The dielectric isolation layer 81 may be formed by depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the dielectric isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L, and are selected based on whether the upper FET is a p-FET or n-FET. Lower nanostructure-FET 10L and upper nanostructure-FET 10U are thus formed.

While the CFET structure (FIG. 12B) include H-shaped channels, it is appreciated that the CFET structure may also have the U-shaped channels or O-shaped channels as shown in FIG. 6C or 6D. For example, the high-Ge SiGe layer 24AH and low-Ge SiGe layer 24AL in FIG. 6C may be replaced with the replacement gate stacks 82U and 82L, which wraps around the U-shape channels including silicon layers 26U/26L and silicon layers 34. Also, in FIG. 12B, U-shaped channels are shown. Similarly, the high-Ge SiGe layer 24AH and low-Ge SiGe layer 24AL in FIG. 6D may be replaced with the replacement gate stacks, which wraps around the O-shape channels including silicon layers 26U/26L and silicon layers 34.

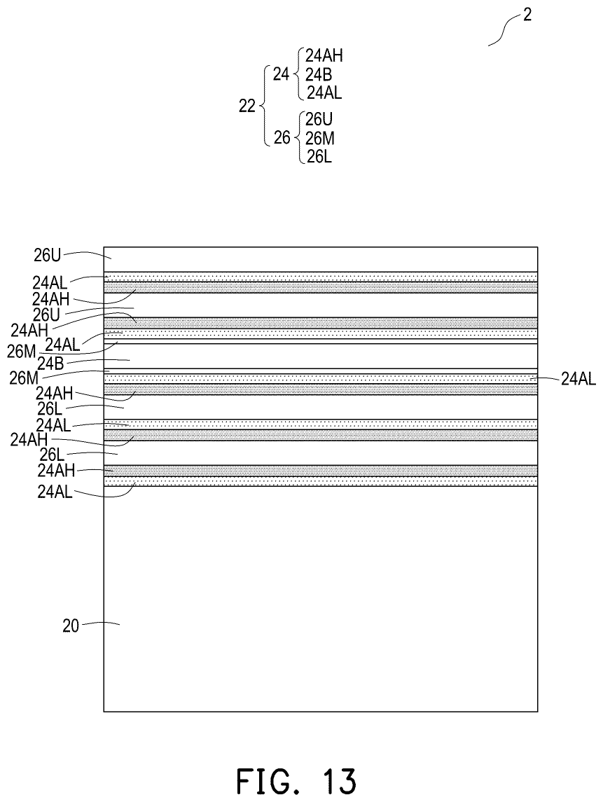

FIG. 13 through FIGS. 19A, 19B, and 19C illustrate the formation of a CFET structure in accordance with alternative embodiments. These embodiments are similar to the preceding embodiments, except that fish-bone shaped channels or grating-shaped channels are formed. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

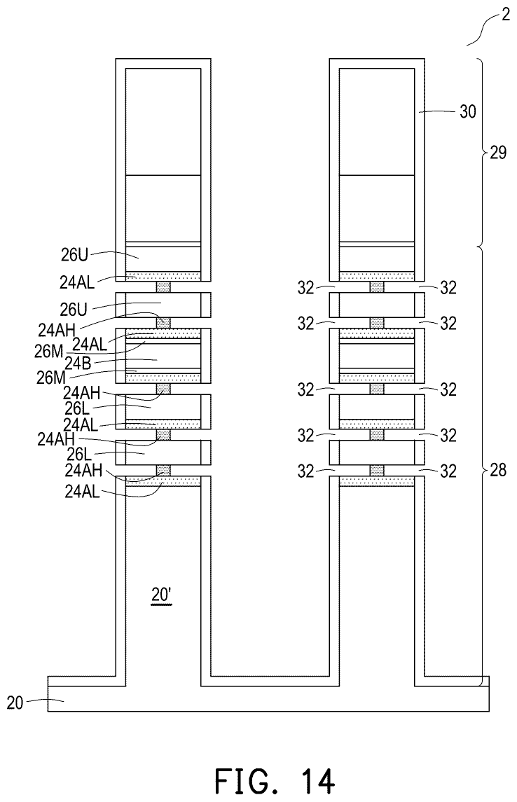

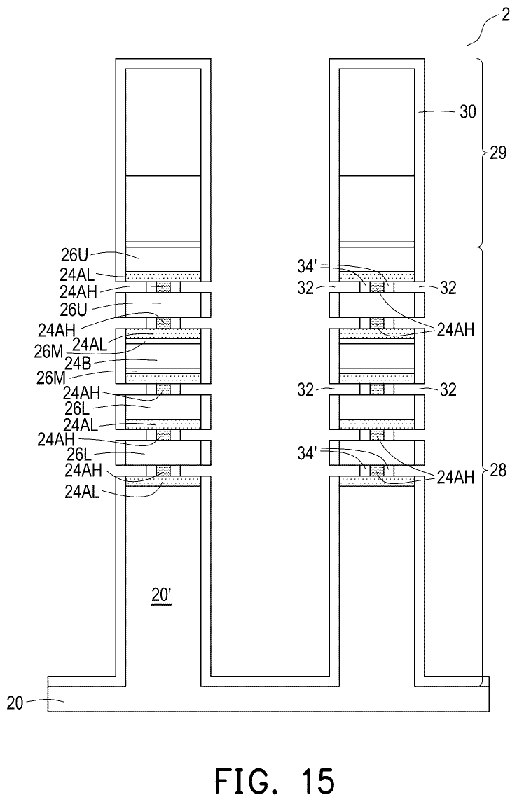

The initial steps of these embodiments are essentially the same as shown in FIGS. 2 through 5, and are also shown in FIGS. 13 and 14, in which the oxide layer 30 is formed, followed by a selective etching process to remove the portions of the oxide layer on the sidewalls of the high-Ge SiGe layers 24AH. Openings 32 are thus formed. The high-Ge SiGe layers 24AH are then laterally recessed. Referring to FIG. 15, silicon nano fins 34′ are deposited. The deposition process is selectively, and comprises an epitaxy process. The process details are essentially the same as the formation of silicon layer 34 as shown in FIG. 6A. The selective deposition is achieved through the different growth rate on the (100) and (110) surfaces as aforementioned. The epitaxy process is stopped before the openings 32 are fully filled. In accordance with some embodiments, silicon nano fins 34′ are free from germanium therein.

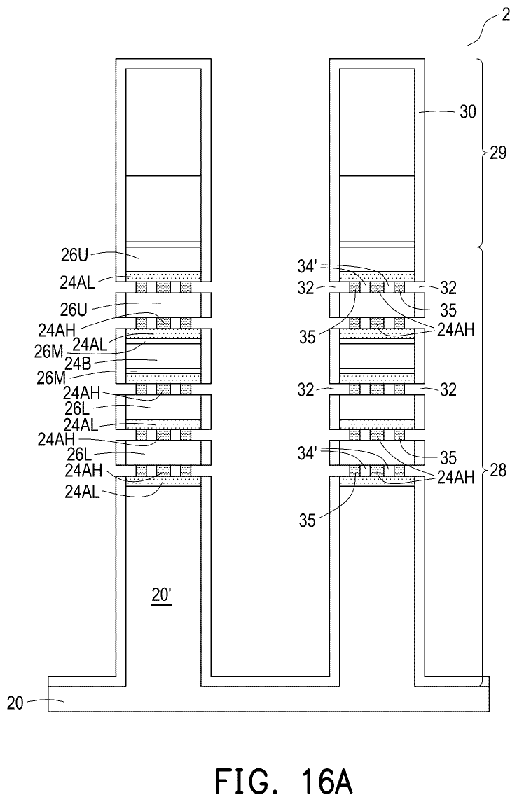

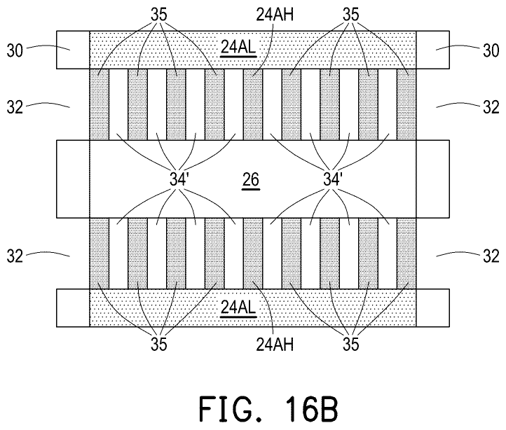

Next, as shown in FIG. 16A, SiGe nano fins 35 are formed through selective epitaxy, which process are similar to the formation of silicon nano fins 34′. In accordance with some embodiments, SiGe nano fins 35 have a germanium atomic percentage in the same range as that of low-Ge SiGe layer 24AL, for example, in the range between about 10 percent and about 35 percent. In accordance with alternative embodiments, SiGe nano fins 35 have a germanium atomic percentage in the same range as that of high-Ge SiGe layer 24AH, for example, in the range between about 35 percent and about 50 percent. The thickness of silicon nano fins 34′ and SiGe nano fins 35 may be controlled by controlling the growth time.

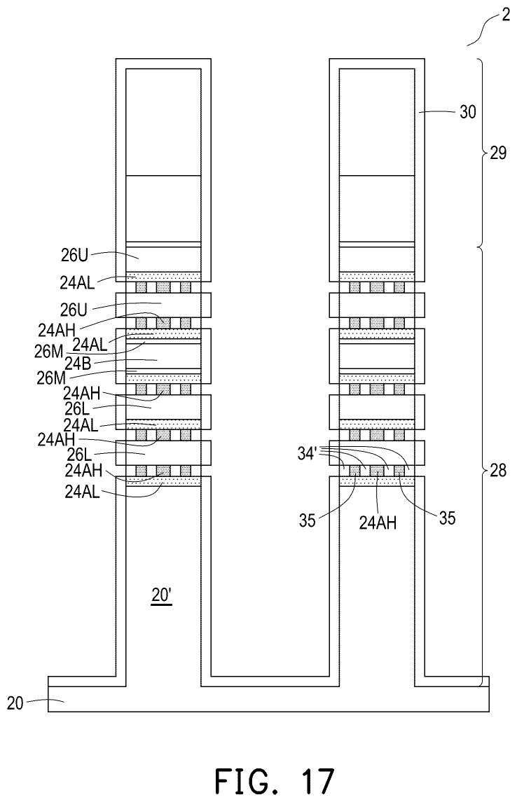

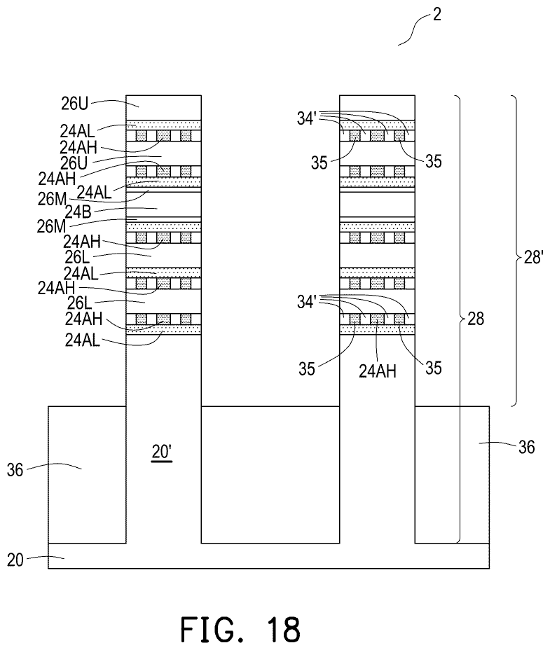

The formation of silicon nano fins 34′ and SiGe nano fins 35 may be repeated one time, two times, three times, or more, creating symmetric structures on opposite sides of the remaining high-Ge SiGe layer 24AH, and hence the total count of silicon nano fins 34′ (or SiGe nano fins 35) may be 2, 4, 6, 8, or more. The process is finished when the openings 32 are filled, as shown in FIG. 17. FIG. 16B illustrates an amplified view of a portion of the grating-shaped structure as shown in FIG. 17, in which a semiconductor nanostructure 26 (26U or 26L) and it overlying and underlying silicon nano fins 34′ collectively form a fishbone shape. Oxide layer 30 is then removed, and the resulting structure is shown in FIG. 18.

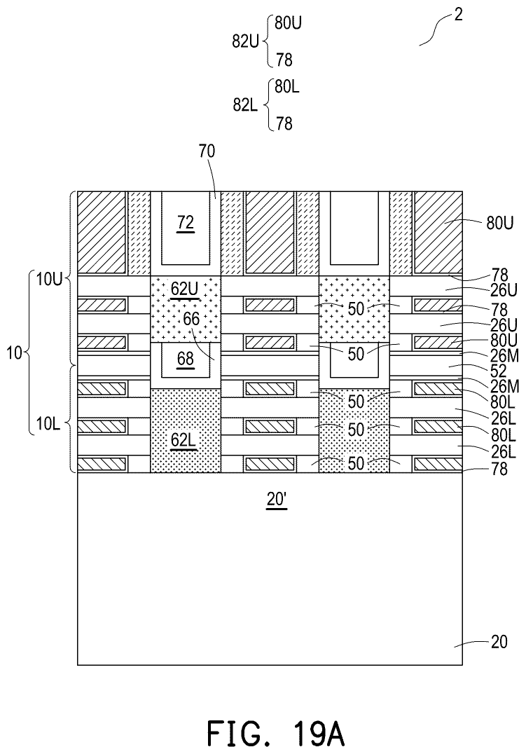

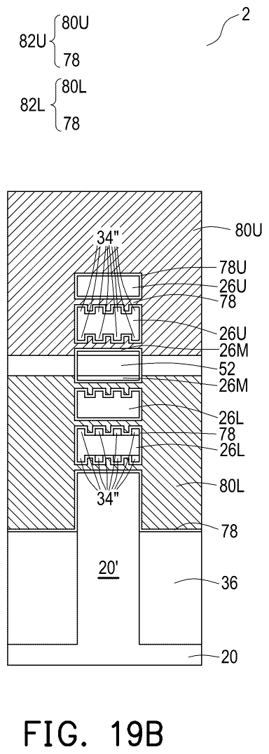

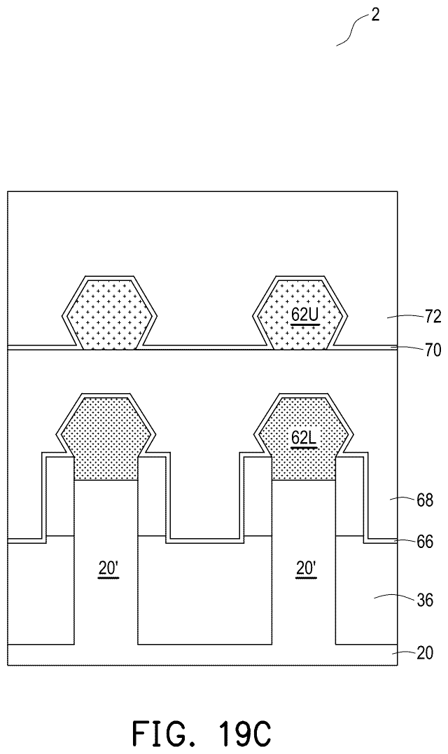

In subsequent processes, the processes similar to the processes as shown in FIGS. 8A, and 8B through FIGS. 12A, 12B, and 12C are performed, and the process details are not repeated herein. The resulting CFET structure is shown in FIGS. 19A, 19B, and 19C. The resulting channel regions (FIG. 19B) have fishbone shapes.

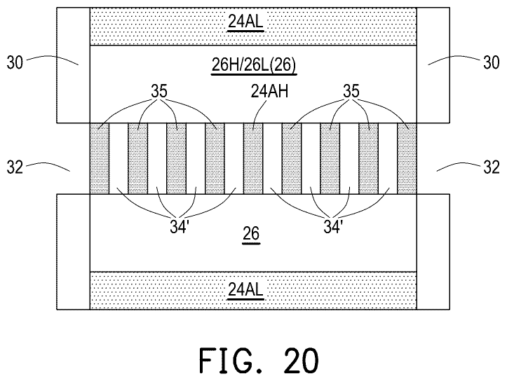

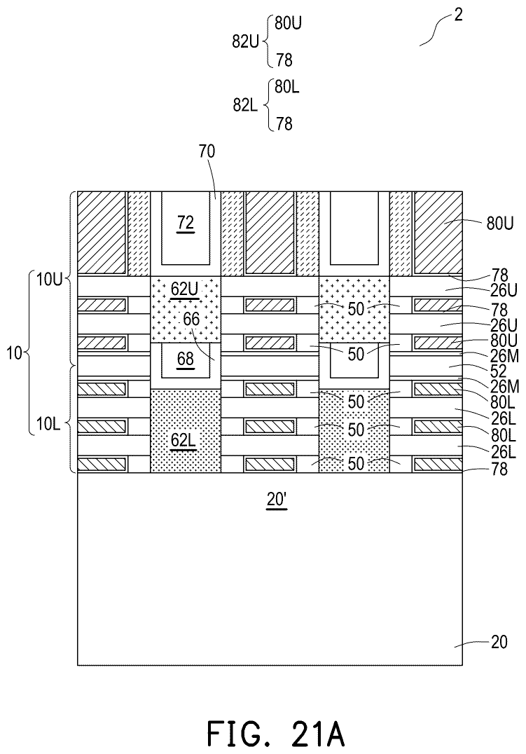

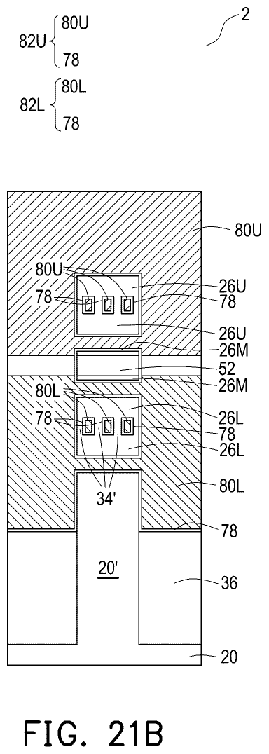

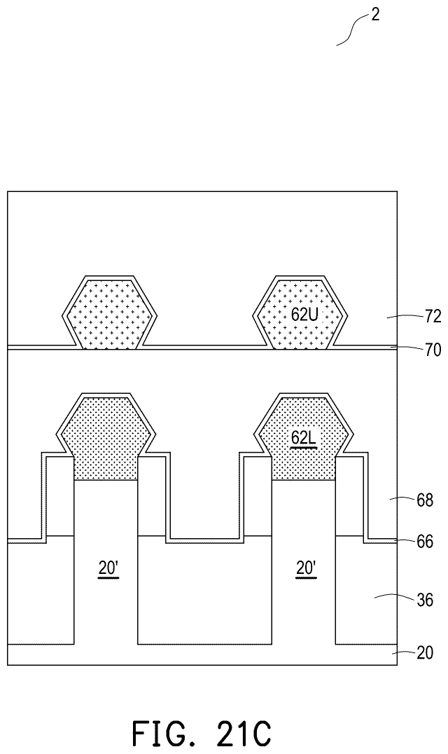

FIGS. 20 and 21 illustrate the formation of a CFET structure having a grating-shaped channel region in accordance with some embodiments. As shown in FIG. 20, a grating-shaped silicon region is formed, wherein the formation processes are essentially the same as shown in FIGS. 13 through 17. The grating-shape includes two silicon layers 26U (or 26L) interconnected by silicon nano fins 34′ and SiGe nano fins 35. The resulting CFET structure is shown in FIGS. 21A, 21B, and 21C, in which the channel regions are formed of silicon, and have a grating shape.

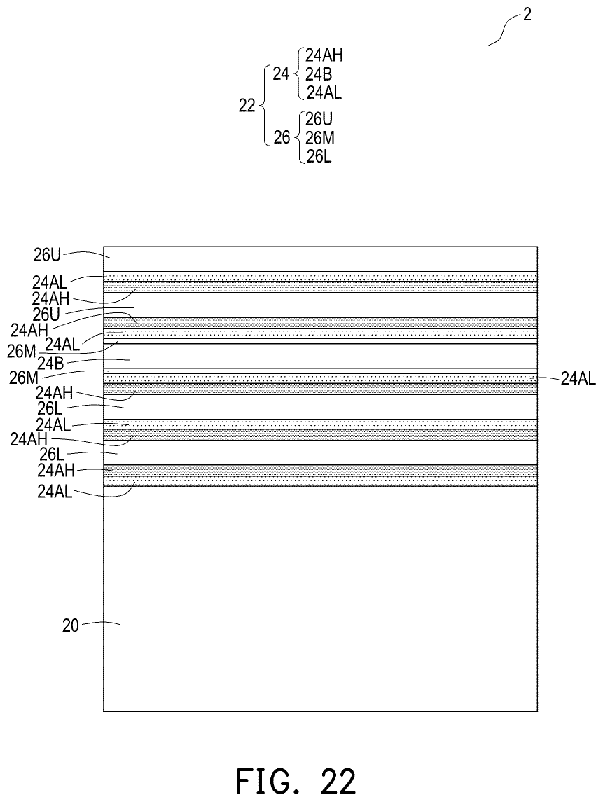

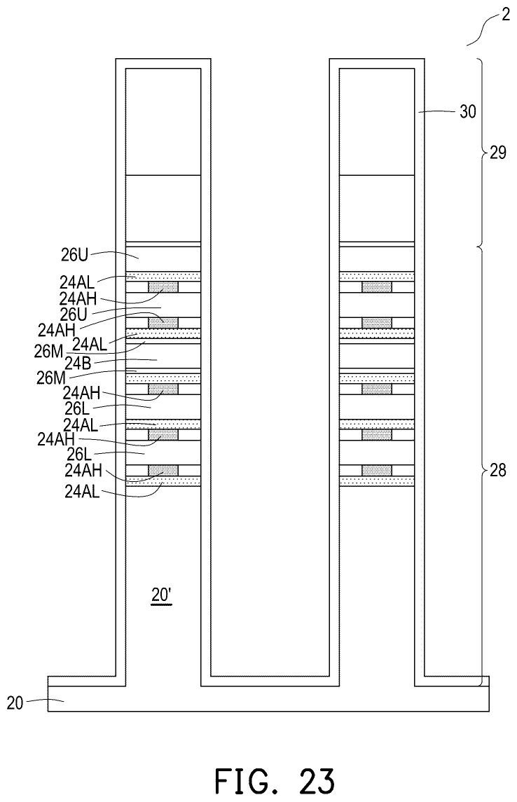

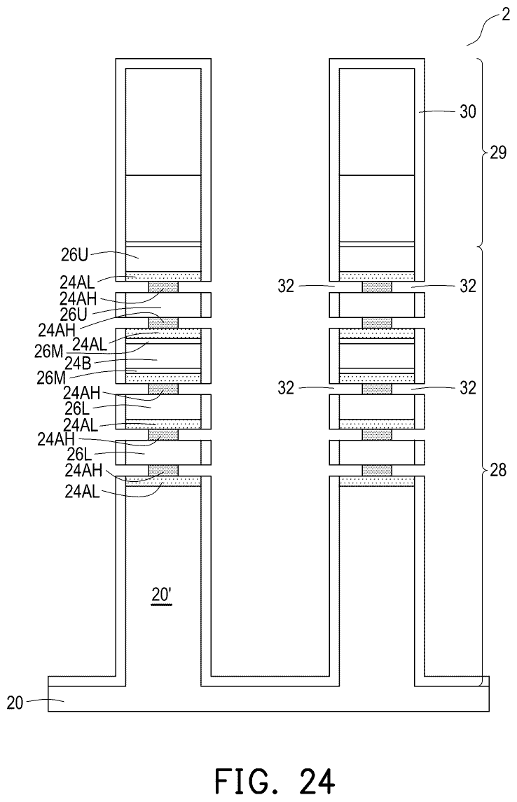

FIG. 22 through FIGS. 28A, 28B, and 28C illustrate the processes for forming an H-shaped channel in accordance with alternative embodiments. These embodiments are similar to the embodiments as shown in FIG. 2 through FIGS. 12A, 12B, and 12C, except that instead of epitaxially growing silicon layers 34 (FIG. 6A), higher-Ge SiGe layers 34″ are epitaxially grown to form the vertical legs of the H-shape. In accordance with some embodiments, the higher-Ge SiGe layers 34″ have a germanium atomic percentage higher than that of the high-Ge SiGe layers 24AH. For example, the germanium atomic percentage of the higher-Ge SiGe layers 34″ may be in the range between about 80 percent and about (and may be equal to) 100 percent.

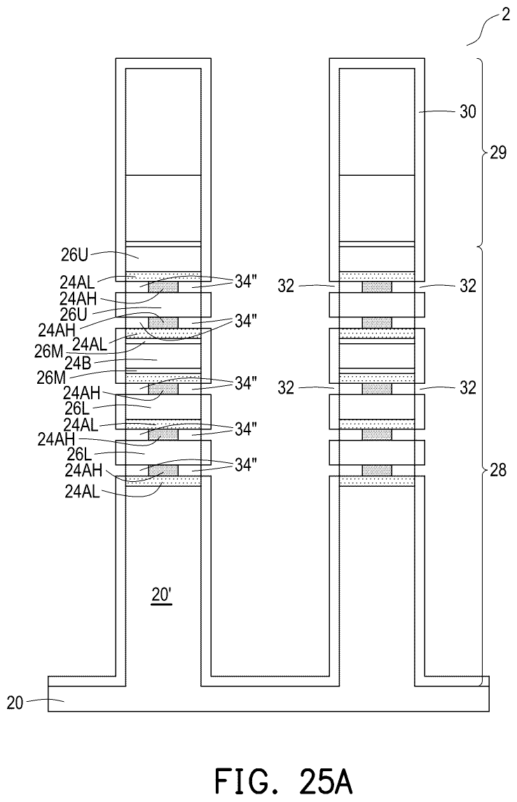

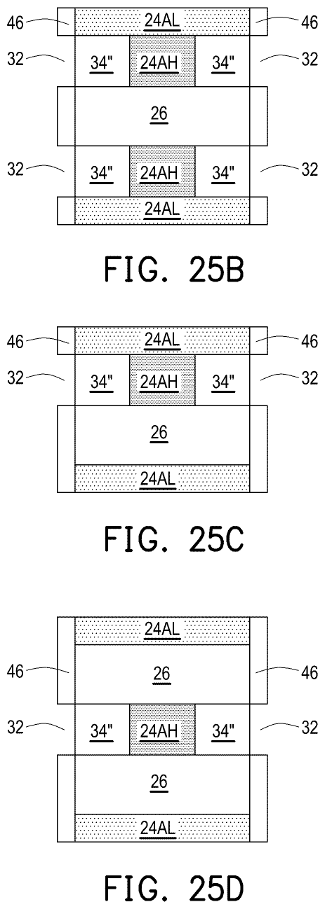

FIGS. 22-24 illustrate the same processes as shown in FIGS. 2-5, and the details are not repeated herein. Next, as shown in FIG. 25A, the higher-Ge SiGe layers 34″ are epitaxially grown. The process details are essentially the same as that described referring to FIG. 6A, except the precursors are selected for growing SiGe or germanium, depending on the germanium atomic percentage of the higher-Ge SiGe layers 34″. FIG. 25A illustrates that the silicon layer 26U (or 26L) and the higher-Ge SiGe layers 34″ collectively form an H-shape, which is also shown in FIG. 25B. FIGS. 25C and 25D illustrate that the silicon layer 26U (or 26L) and the higher-Ge SiGe layers 34″ collectively form a U-shape or an O-shape, respectively.

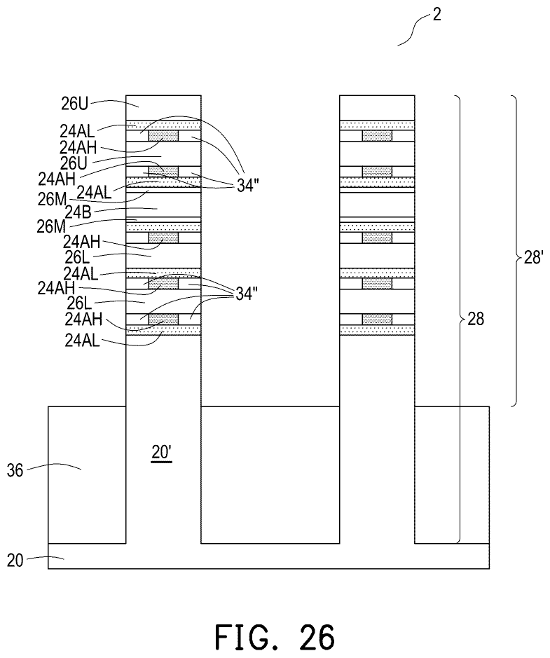

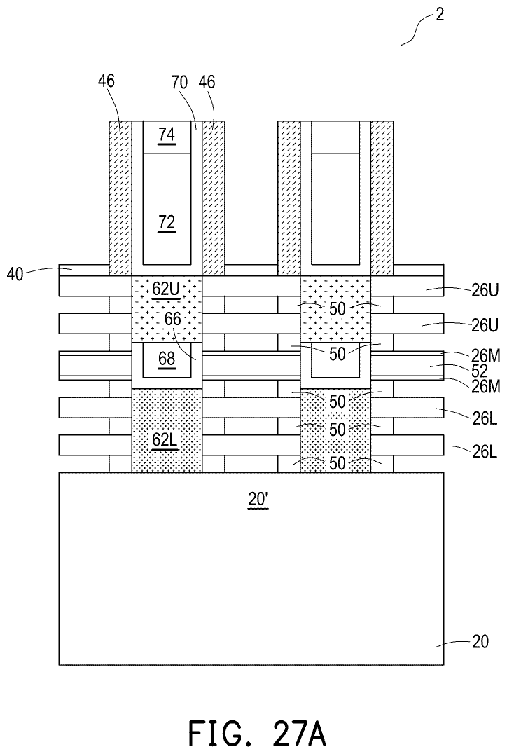

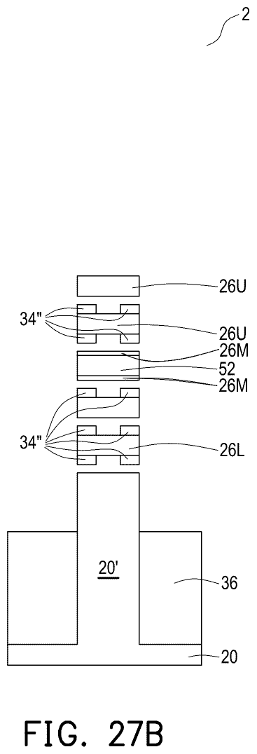

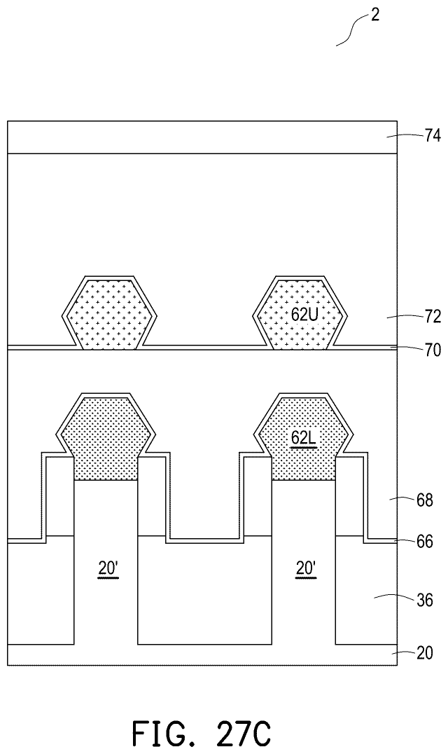

FIG. 26 illustrates the removal of oxide layer 30. Next, high-Ge SiGe layers 24AH and low-Ge SiGe layers 24AL are removed in a selective etching process, while higher-Ge SiGe layers 34″ and silicon layers 26 remain. The resulting structure is shown in FIGS. 27A, 27B, and 27C. The etching may be achieved by adopting an etching chemical selected from Tetramethylammonium hydroxide (TMAH), the mixture of HF, deionized water, hydrogen peroxide (H₂O₂), Ge-inhibitor, the mixture of SF₆ and H₂, or the like.

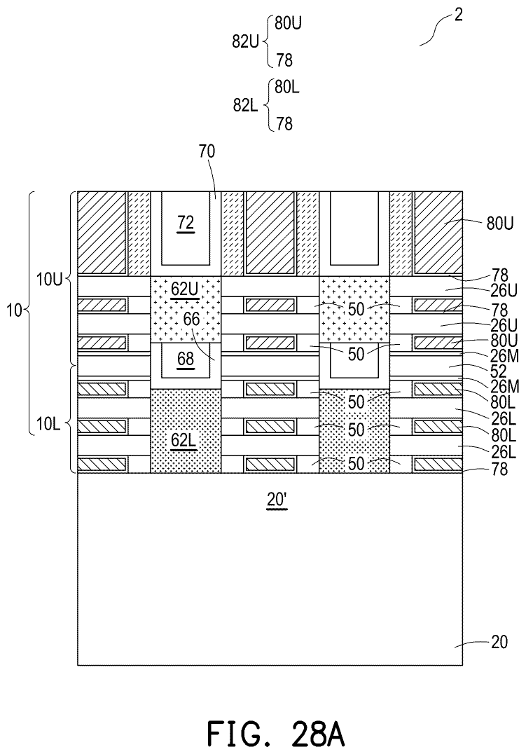

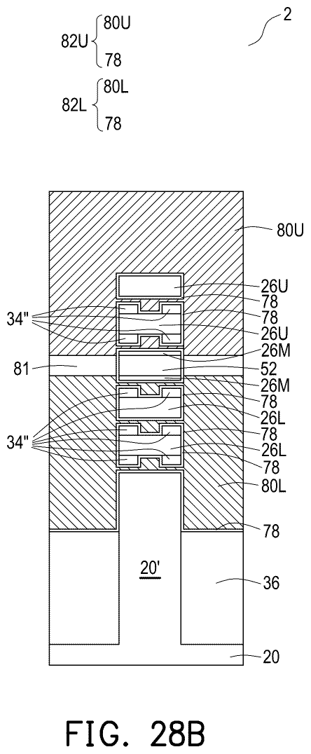

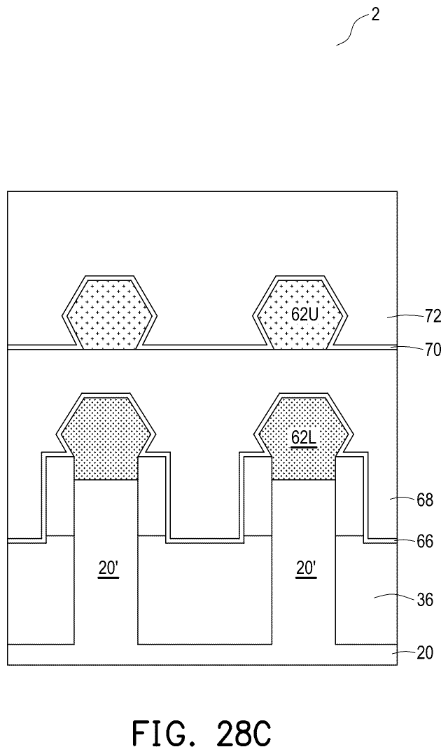

FIGS. 28A, 28B, and 28C illustrate the formation of replacement gate stacks 82L and 82U, and hence CFET structure 10 is formed. The resulting channel regions (FIG. 28B) may have an H-shape (and also a U-shape), and the channel regions include silicon layers 26U or 26L combined with the higher-Ge SiGe layers 34″.

In accordance with alternative embodiments, the structures shown in FIGS. 25C and 25D may be adopted, with the high-Ge SiGe layers 24AH and low-Ge SiGe layers 24AL replaced with replacement gate stacks. The resulting CFETs include a U-shape channel region (resulted from FIG. 25C) or an O-shaped channel region (resulted from FIG. 25D).

It is appreciated that the CFET structures in above-discussed embodiments have increased effective channel width. These CFET structures may be formed in the same die, and possibly formed together with the CFETs that have planar semiconductor nanostructures as channel regions. This results in increased ability for tuning the drive currents of the CFETs.

The embodiments of the present disclosure have some advantageous features. By selectively depositing silicon, SiGe, or Ge on the planar nanostructures (such as silicon nanostructures), the channel regions of the CFETs have increased effective channel width. Also, the ability of tuning device performance is improved.

In accordance with some embodiments of the present disclosure, a method comprises forming a multi-layer stack comprising a plurality of semiconductor nanostructures, wherein the multi-layer stack comprises a first semiconductor nanostructure; and a first sacrificial semiconductor layer over the first semiconductor nanostructure; depositing a first semiconductor layer over and contacting the first semiconductor nanostructure; removing the first sacrificial semiconductor layer; and forming a first replacement gate stack encircling a combined region of the first semiconductor nanostructure and the first semiconductor layer.

In an embodiment, the depositing the first semiconductor layer comprises depositing a silicon layer. In an embodiment, the depositing the first semiconductor layer comprises depositing a germanium-containing semiconductor layer. In an embodiment, the method further comprises laterally recessing the first sacrificial semiconductor layer to leave a space, wherein the first semiconductor layer is deposited in the space. In an embodiment, the multi-layer stack comprises a semiconductor nano fin, and the method further comprises depositing a sacrificial nano fin; and removing the sacrificial nano fin to leave an additional space, wherein the first replacement gate stack further comprises a portion in the additional space.

In an embodiment, the depositing the first semiconductor layer comprises a selective epitaxy process. In an embodiment, the method further comprises depositing a second semiconductor layer under and contacting the first semiconductor nanostructure, wherein the first replacement gate stack wraps around an H-shaped semiconductor region that comprises the first semiconductor nanostructure, the first semiconductor layer, and the second semiconductor layer. In an embodiment, the first replacement gate stack wraps around a U-shaped semiconductor region that comprises the first semiconductor nanostructure and the first semiconductor layer.

In an embodiment, the first replacement gate stack wraps around an O-shaped semiconductor region that comprises the first semiconductor nanostructure and the first semiconductor layer. In an embodiment, the multi-layer stack further comprises a second semiconductor nanostructure overlapping the first semiconductor nanostructure, and the method further comprises forming a second replacement gate stack encircling the second semiconductor nanostructure, wherein the first replacement gate stack and the second replacement gate stack are comprised in a CFET structure.

In accordance with some embodiments of the present disclosure, a structure comprises a first semiconductor region comprising a first semiconductor nanostructure; and a first semiconductor layer and a second semiconductor layer over and contacting the first semiconductor nanostructure; a first gate stack comprising a first portion over and contacting the first semiconductor nanostructure, wherein the first portion is located between the first semiconductor layer and the second semiconductor layer; and a second portion under and contacting the first semiconductor nanostructure; and a source/drain region aside of and contacting the first semiconductor nanostructure.

In an embodiment, the first semiconductor region has an H-shaped cross-sectional view. In an embodiment, the first semiconductor region has a U-shaped cross-sectional view. In an embodiment, the first semiconductor region has an O-shaped cross-sectional view. In an embodiment, the first semiconductor nanostructure comprises a first silicon layer, and the first semiconductor layer and the second semiconductor layer are second silicon layers.

In an embodiment, the first semiconductor nanostructure comprises a silicon layer, and the first semiconductor layer and the second semiconductor layer are germanium-containing layers. In an embodiment, the structure further comprises a second semiconductor region; and a second gate stack comprising a third portion over and contacting the second semiconductor region; and a fourth portion under and contacting the second semiconductor region, wherein the second semiconductor region and the second gate stack overlap the first semiconductor region and the first gate stack.

In accordance with some embodiments of the present disclosure, a structure comprises a first transistor comprising a semiconductor region, wherein in a cross-sectional view of the structure, the semiconductor region has a cross-sectional view shape selected from an H-shape, a U-shape, and an O-shape; a first gate stack encircling, and physically contacting, a part of the semiconductor region; and a source/drain region aside of and contacting the semiconductor region; and a second transistor overlapping the first transistor. In an embodiment, the semiconductor region comprises silicon. In an embodiment, the semiconductor region comprises a first portion comprising silicon, and a second portion comprising germanium.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a multi-layer stack comprising a plurality of semiconductor nanostructures, wherein the multi-layer stack comprises:
a first semiconductor nanostructure; and
a first sacrificial semiconductor layer over the first semiconductor nanostructure;
depositing a first semiconductor layer over and contacting the first semiconductor nanostructure;
removing the first sacrificial semiconductor layer; and
forming a first replacement gate stack encircling a combined region of the first semiconductor nanostructure and the first semiconductor layer, wherein the depositing the first semiconductor layer comprises depositing a silicon layer, and wherein the depositing the first semiconductor layer comprises depositing a germanium-containing semiconductor layer.
